(19) United States
(12) Patent Application Publication
(10) Pub. No.: US 2010/0291308 A1
(43) Pub. Date: Nov. 18, 2010

(54) Web Substrate Deposition System

(75) Inventors: Piero Sferlazzo, Marblehead, MA (US); Martin Klein, Bedford, MA (US)

Correspondence Address: RAUSCHENBACH PATENT LAW GROUP, LLP, P.O. BOX 387, BEDFORD, MA, 01730, US

(73) Assignee: VEECO INSTRUMENTS INC., Plainview, NY (US)

(21) Appl. No.: 12/466,221

(22) Filed: May 14, 2009

(51) Int. Cl. B05D 3/00; C23C 16/56; B05C 9/12; C23C 14/35

(52) U.S. Cl. 427/398.1; 118/724; 118/69; 204/298.16; 204/298.09

(57) ABSTRACT

A deposition system includes a drum for supporting a web substrate during deposition that defines a plurality of apertures in an outer surface for passing cooling gas. A gas manifold includes an input that is coupled to an output of a gas source and at least one output that is coupled to the plurality of apertures in the outer surface of the drum. The gas manifold provides gas to the plurality of apertures that flows between the outer surface of the drum and the web substrate, thereby increasing heat transfer from the web substrate to the drum. At least one deposition source is positioned so that material deposits on the web substrate.

The section headings used herein are for organizational purposes only and should not to be construed as limiting the subject matter described in the present application in any way.

### INTRODUCTION

The present invention relates to web substrate deposition systems. Web substrate deposition systems have been used for processing webs of numerous types of flexible substrate materials for many years. In these deposition systems, the plastic web is tightly spooled over a rotating cooling drum positioned above an evaporation source. The plastic web material receives a very high heat load during deposition from condensing metal and from radiant heat which typically increases with the deposition rate. Thus, when operating at high transport rates to achieve high coating speeds, this heat load may cause the web material to wrinkle and crease on the drum. This wrinkling and creasing on the drum can permanently damage the web substrate. The thermal conductance between the web substrate and the cooling drum plays an important role in controlling the temperature rise of the web substrate as it is coated. The temperature rise is important because it sets an upper limit on the coating speed for a given web substrate and deposition process.

### BRIEF DESCRIPTION OF THE DRAWINGS

The present teachings, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale, emphasis instead generally being placed upon illustrating principles of the invention. The drawings are not intended to limit the scope of the Applicant's teachings in any way.

FIG. 1 illustrates a web substrate deposition system according to the present invention which includes a drum that defines a plurality of apertures in an outer surface for passing cooling gas.

FIG. 2A illustrates a drum for a web substrate deposition system according to the present invention that includes one embodiment of a combination gas manifold/sliding seal where the combination gas manifold/sliding seal is positioned in a fixed location and the drum rotates relative to the combination gas manifold/sliding seal.

FIG. 2B illustrates a drum for a web substrate deposition system according to the present invention that includes a rotary valve positioned in the center of the drum that controls the flow of cooling gas to a plurality of apertures.

FIG. 3 illustrates another web substrate deposition system according to the present invention which includes at least two cooling drums that define a plurality of apertures in an outer surface for passing cooling gas and a deposition source having an output that is positioned so that material deposits on the web substrate in a region between the at least two cooling drums.

### DESCRIPTION OF VARIOUS EMBODIMENTS

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

It should be understood that the individual steps of the methods of the present teachings may be performed in any order and/or simultaneously as long as the invention remains operable. Furthermore, it should be understood that the apparatus and methods of the present teachings can include any number or all of the described embodiments as long as the invention remains operable.

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications, and equivalents, as will be appreciated by those of skill in the art. Those of ordinary skill in the art having access to the teachings herein will recognize additional implementations, modifications, and embodiments, as well as other fields of use, which are within the scope of the present disclosure as described herein.

The present invention relates to web substrate deposition systems that include at least one deposition source that deposits material on a portion of the web substrate while it transports over a drum or between two drums. The web substrate can experience large temperature changes in localize regions where the deposition source deposits material on the surface of the web substrate. The web substrates cannot easily dissipate the heat generated during deposition because they have a low thermal mass and because they are positioned in a vacuum environment that does not transfer heat well. Therefore, the portion of the web substrate that is exposed to the deposition source will not return to ambient temperatures before it is again exposed to the deposition source. Consequently, the web substrate will experience a temperature increase during the deposition process, which limits the deposition rate and the total film thickness that can be obtained in a single deposition.

The temperature increase that is experienced by the web substrate can also affect the deposited film properties. The web substrate and the deposited material will typically have different thermal expansion coefficients so that, as they cool, they will contract at different rates. The different thermal expansion coefficients can add a stress at the coating/substrate interface and can change the shape of the coated substrate. A high stress at the coating/substrate interface can cause buckling and/or cracking of the deposited film and can also result in poor adhesion or a total loss of adhesion of the deposited film to the web substrate.

There have been attempts to construct web substrate deposition systems that efficiently transfer heat from the drums so as to reduce localized heating of the web substrate. See, for example, U.S. Pat. No. 5,076,203, which describes an apparatus that includes a gas source external to the drum, which introduces a cooling gas between the web substrate and the drum with an injection mechanism. The injected cooling gas increases the heat transfer and reduces the friction between the web substrate and the drum. The gas injected between the web substrate and the drum, however, quickly leaks out at the edges which, increases the pressure in the region where material is being deposited. The increased pressure in the region where material is being deposited on the web substrate can be mitigated somewhat by increasing the vacuum pumping speed. However, this increase in pressure typically results in undesirable deposition properties, which can change the structure of the deposited film.

One aspect of the web substrate deposition system of the present invention is that it can simultaneously increase heat transfer from the web substrate to the drum while still maintaining a low pressure proximate to the portion of the web substrate being exposed to the deposition source. Such web substrate deposition systems can be used to deposit material onto web substrates at higher deposition rates. Such web substrate deposition systems can also be used to deposit material onto web substrates with lower processing temperature requirements. In addition, such web substrate deposition systems can deposit films on web substrates with superior film qualities.

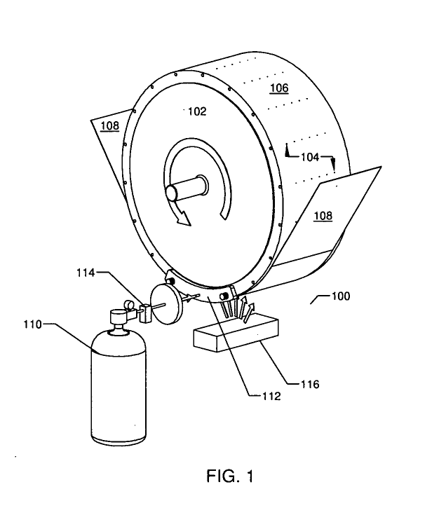

FIG. 1 illustrates a web substrate deposition system 100 according to the present invention which includes a drum 102 that defines a plurality of apertures 104 in an outer surface 106 for passing cooling gas. The drum 102 supports a web substrate 108 during deposition. In various embodiments, at least some of the plurality of apertures 104 has a diameter that is in a range of approximately 0.1 mm to 10 mm. Each of the plurality of apertures 104 can have the same diameter or some or all of the plurality of apertures 104 can have a different diameter. In one embodiment, the drum 102 includes at least one conduit for passing cooling fluid that is used to controls the temperature of the drum 102.

In some embodiments, the drum 102 includes an elastomeric coating that is formed on the outer surface of the drum 106 that increases heat transfer between the web substrate 108 and the drum 102. The elastomeric coating can have holes that match the plurality of apertures 104 so that the cooling gas is transferred through the elastomeric coating to the web substrate 108. In one embodiment, the elastomeric coating is formed of a permeable membrane material.

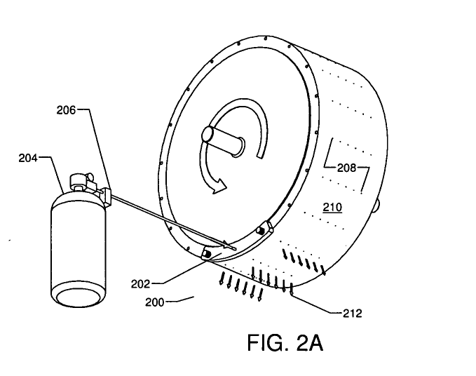

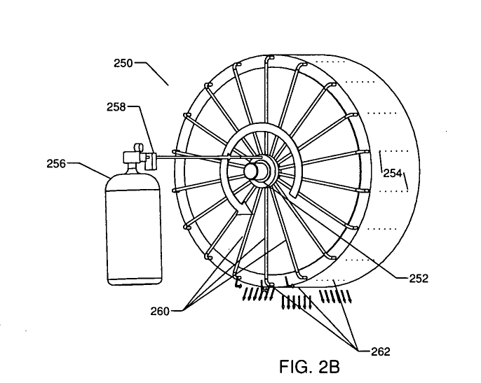

In some embodiments, the drum 102 includes a sliding seal that covers at least some of the plurality of apertures 104 in the outer surface 106 of the drum 102 as described in connection with FIG. 2. In one specific embodiment, the sliding seal covers substantially all of the plurality of apertures 104 in the outer surface 106 of the drum 102 except the apertures that are in contact with the web substrate 108 so as to minimize the volume of cooling gas introduced into the chamber and the resulting increase in pressure proximate to the deposition area.

The web substrate deposition system 100 also includes a gas source 110 and a gas manifold 112 that provides the cooling gas to the drum 102. In some embodiments, the gas source 110 is positioned outside the drum 102 as shown in FIG. 1. However, in other embodiments, the gas source 110 is positioned inside the drum 102. The gas source 110 can contain any type of cooling gas, such as He gas. The gas manifold 112 has an input that is coupled to an output of the gas source 110 and at least one output that is coupled to the plurality of apertures 104 in the outer surface 106 of the drum 102. The gas manifold 112 provides the cooling gas to the plurality of apertures 104 that flows between the outer surface 106 of the drum 102 and the web substrate 108, which increases heat transfer from the web substrate 108 to the drum 102. A gas solenoid 114 is coupled between the gas source 110 and the gas manifold 112. The gas solenoid 114 controls a flow of gas to the plurality of apertures 104, which then controls the heat transfer from the web substrate 108 to the drum 102.

The web substrate deposition system 100 includes at least one deposition source 116 which has an output that is positioned so that material deposits on the web substrate 108. Any type of deposition source can be used. For example, at least one deposition source 116 can include a magnetron sputtering source. Also, the at least one deposition source 116 can include a thermal or electron beam evaporation source. For example, in one embodiment, the deposition source 116 is a Cu/In/Ga source.

Referring to FIG. 1, a method of depositing material on a web substrate 108 according to the present invention includes supporting the web substrate 108 on an outer surface 106 of a drum 102 that defines a plurality of apertures 104 for passing cooling gas. In some embodiments, an elastomeric coating is formed on the outer surface of the drum 102 to increases heat transfer between the web substrate 108 and the drum 102. In some embodiments, at least some of the plurality of apertures 104 in the outer surface 106 of the drum 102, which are not adjacent to the web substrate 108, are blocked or otherwise restrict the flow of cooling gas so as to reduce the volume of cooling gas entering into the vacuum chamber containing the drum 102 and web substrate 108.

Material is then deposited on the web substrate 108 with the deposition source 116. Cooling gas is provided to the plurality of apertures 104 that flows between the outer surface 106 of the drum 102 and the web substrate 108, thereby increasing heat transfer from the web substrate 108 to the drum 102. Any type of cooling gas can be used. For example, in one embodiment, the cooling gas is He gas.

The heat transfer from the web substrate 108 to the drum 102 is controlled by various means. For example, the flow rate of the cooling gas can be controlled to control the heat transfer from the web substrate 108 to the drum 102. That is, the flow rate of the cooling gas can be controlled so that a pressure of cooling gas between the drum 102 and the web substrate 108 is in the range of 10-50 Torr. In addition, cooling gas can be passed through the drum 102 to control a temperature of the drum 102. Reducing the temperature of the drum 102 will result in the drum 102 sinking more heat from the web substrate 108.

In addition, the cooling gas flowing between the drum 102 and the web substrate 108 tends to cause a portion of the web substrate 108 to float on a layer of trapped cooling gas. The trapped layer of cooling gas between the drum 102 and the web substrate 108 increases the heat transfer coefficient allowing a higher deposition rate. In addition, the trapped layer of cooling gas allows a portion of the web substrate 108 to change shape and to adjust its dimensions so as to mitigate stress and reduce any wrinkles in the web substrate 108 due to thermal expansion caused by temperature changes resulting from the deposition of material on the web substrate 108.

In one embodiment, the web substrate deposition system 100 is used to fabricate copper indium gallium selenide (CIGS) photovoltaic cells. Copper indium gallium selenide photovoltaic cells are second generation solar cells that have relatively high conversion efficiencies and relatively low fabrication costs. The CIGS material is deposited by a deposition source that co-evaporates or co-sputters copper, gallium, indium and selenium onto a heated web substrate material.

FIG. 2A illustrates a drum 200 for a web substrate deposition system according to the present invention that includes one embodiment of a combination gas manifold/sliding seal 202 where the combination gas manifold/sliding seal 202 is positioned in a fixed location and the drum 200 rotates relative to the combination gas manifold/sliding seal 202. A gas source 204 is coupled directly to the combination gas manifold/sliding seal 202 through a control valve 206, which simplifies construction and maintenance.

In this embodiment, the combination gas manifold/sliding seal 202 is positioned in a fixed location where the web substrate contacts the drum 200 and the drum 200 rotates relative to the combination gas manifold/sliding seal 202. FIG. 2A illustrates a counter clockwise rotation, but clockwise rotation is also possible. The combination gas manifold/sliding seal 202 covers at least some of the plurality of apertures 208 in the outer surface 210 of the drum 200 that are not exposed to the web substrate. The drum 200 shown in FIG. 2A illustrates gas entering into the manifold and exiting only through the apertures 212 that are positioned adjacent to the combination gas manifold/sliding seal 202.

FIG. 2B illustrates a drum 250 for a web substrate deposition system according to the present invention that includes a rotary valve 252 positioned in the center of the drum 250 that controls the flow of cooling gas to a plurality of apertures 254. A cooling gas source 256 is coupled directly to the rotary valve 252 through a gas solenoid 258, which simplifies construction and maintenance. As the drum 250 rotates, the rotary valve 252 allows cooling gas to flow only through gas conduits 260 which are connected to apertures 262 in the drum 250 where the drum 250 is in contact with the web substrate.

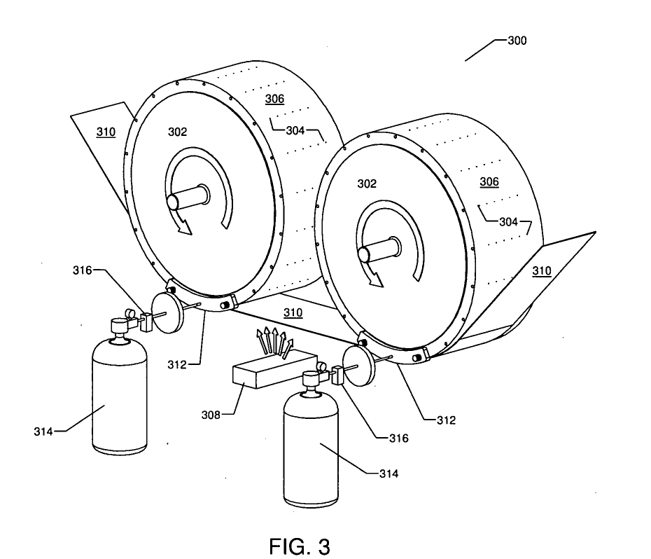

FIG. 3 illustrates another web substrate deposition system 300 according to the present invention which includes at least two cooling drums 302 that define a plurality of apertures 304 in an outer surface 306 for passing cooling gas and a deposition source 308 having an output that is positioned so that material deposits on the web substrate 310 in a region between the at least two cooling drums 302. The web substrate deposition system 300 is similar to the web substrate deposition system 100 that was described in connection with FIG. 1. However, the web substrate deposition system 300 includes multiple cooling drums 302 and the deposition source 308 is positioned to deposit material at a location between the at least two cooling drums 302.

The at least two cooling drums 302 can include sliding seals that cover at least some of the plurality of apertures 304 in the outer surface 306 of the at least two cooling drums 302. In one specific embodiment, the sliding seals cover substantially all of the plurality of apertures 304 in the outer surface 306 of the at least two cooling drums 302 except the apertures that are in contact with the web substrate 310 so as to minimize the volume of cooling gas introduced into the chamber. For example, the at least two cooling drums 302 can include the sliding seals described in connection with FIG. 2A.

Also, the at least two cooling drums 302 can include the rotary valve that is described in connection with FIG. 2B that allows cooling gas to flow only through gas conduits which are connected to apertures 304 in the drums 302 where the drums 302 are in contact with the web substrate. In addition, the at least two drums 302 can include at least one conduit for passing cooling fluid that is used to control the temperature of the at least two drums 302.

The web substrate deposition system 300 also includes a gas manifold 312 for each of the at least two cooling drums 302. In various embodiments, one or more gas manifolds 312 can be used to provide gas to the at least two cooling drums 302. An input of each of the one or more gas manifolds 312 is coupled to an output of a gas source 314. At least one output of each gas manifold 312 is coupled to the plurality of apertures 304 defined by each of the at least two cooling drums 302. The gas manifold 312 provides cooling gas to the plurality of apertures 304 that flows between the outer surfaces 306 of the at least two cooling drums 302 and the web substrate 310, which increases heat transfer from the web substrate 310 to the at least two cooling drums 302.

Gas solenoids 316 can be coupled between the gas source 314 and the gas manifold 312 for each of the at least two cooling drums 302. The gas solenoids 316 control a flow of gas to the plurality of apertures 304, which then controls the heat transfer from the web substrate 310 to the drum 302. In some embodiments, a separate gas source is positioned in each of the at least two drums 302.

The at least one deposition source has an output that is positioned so that material deposits on the web substrate 310 between the at least two cooling drums 302. Any type of deposition source can be used, such as a magnetron sputtering source or a thermal evaporation source.

### Equivalents

While the Applicant's teachings are described in conjunction with various embodiments, it is not intended that the Applicant's teachings be limited to such embodiments. On the contrary, the Applicant's teachings encompass various alternatives, modifications, and equivalents, as will be appreciated by those of skill in the art, which may be made therein without departing from the spirit and scope of the teaching.

What is claimed is:

1. A deposition system comprising:
a. a drum for supporting a web substrate during deposition, the drum defining a plurality of apertures in an outer surface for passing cooling gas;
b. a gas manifold having an input that is coupled to an output of a gas source and at least one output that is coupled to the plurality of apertures in the outer surface of the drum, the gas manifold providing gas to the plurality of apertures that flows between the outer surface of the drum and the web substrate, thereby increasing heat transfer from the web substrate to the drum; and
c. at least one deposition source having an output that is positioned so that material deposits on the web substrate.

2. The deposition system of claim 1 wherein the gas source comprises a He gas.

3. The deposition system of claim 1 wherein the gas source is positioned external to the drum.

4. The deposition system of claim 1 further comprising a gas solenoid that is coupled between the gas source and the manifold, the gas solenoid controlling a flow of gas to the plurality of apertures, thereby controlling heat transfer from the web substrate to the drum.

5. The deposition system of claim 1 wherein the at least one deposition source comprises a magnetron sputtering source.

6. The deposition system of claim 1 wherein the at least one deposition source comprises a thermal evaporation source.

7. The deposition system of claim 1 wherein a diameter of the plurality of apertures in the outer surface of the drum is chosen so that a pressure proximate to the web substrate is in the range of 10-50 Torr.

8. The deposition system of claim 1 wherein the drum comprises an elastomeric coating formed on the outer surface of the drum that increases heat transfer between the web substrate and the drum.

9. The deposition system of claim 1 wherein the drum comprises at least one conduit for passing fluid that controls a temperature of the drum.

10. The deposition system of claim 1 wherein at least one of the plurality of apertures comprises a diameter that is in a range of approximately 0.1 mm to 10 mm.

11. The deposition system of claim 1 wherein the drum further comprises a sliding seal that covers at least some of the plurality of apertures in the outer surface of the drum.

12. The deposition system of claim 1 wherein the drum further comprises a rotary valve that covers at least some of the plurality of apertures in the outer surface of the drum.

13. A deposition system comprising:
a. at least two cooling drums for supporting a web substrate during deposition, each of the at least two cooling drum defining a plurality of apertures in an outer surface for passing cooling gas;
b. a gas manifold having an input that is coupled to an output of a gas source and at least one output that is coupled to the plurality of apertures defined by each of the at least two cooling drums, the gas manifold providing gas to the plurality of apertures that flows between the outer surfaces of the at least two cooling drums and the web substrate, thereby increasing heat transfer from the web substrate to the at least two cooling drums; and
c. at least one deposition source having an output that is positioned so that material deposits on the web substrate in a region between the at least two cooling drums.

14. The deposition system of claim 13 wherein the gas source comprises a He gas.

15. The deposition system of claim 13 wherein the gas source is positioned external to the drum.

16. The deposition system of claim 13 further comprising a gas solenoid that is coupled between the gas source and the manifold, the gas solenoid controlling a flow of gas to the plurality of apertures in each of the at least two cooling drums, thereby controlling heat transfer from the web substrate to the at least two cooling drum.

17. The deposition system of claim 13 wherein the at least one deposition source comprises a magnetron sputtering source.

18. The deposition system of claim 13 wherein the at least one deposition source comprises a thermal evaporation source.

19. The deposition system of claim 13 wherein a diameter of the plurality of apertures in the outer surface of the at least two drums is chosen so that a pressure proximate to the web substrate is in the range of 10-50 Torr.

20. The deposition system of claim 13 wherein the at least two cooling drums comprise an elastomeric coating formed on the outer surfaces of the at least two cooling drums that increases heat transfer between the web substrate and the drum.

21. The deposition system of claim 13 wherein the at least two cooling drums comprise at least one conduit for passing fluid that controls a temperature of the at least two cooling drums.

22. The deposition system of claim 13 wherein at least one of the plurality of apertures in the at least two cooling drums comprises a diameter that is in a range of approximately 0.1 mm to 10 mm.

23. The deposition system of claim 13 wherein the at least two cooling drums further comprises a sliding seal that covers at least some of the plurality of apertures in the outer surface of the drum.

24. The deposition system of claim 13 wherein the at least two cooling drums further comprises a rotary valve that covers at least some of the plurality of apertures in the outer surface of the drum.

25. A method of depositing material on a web substrate, the method comprising:
a. supporting a web substrate on an outer surface of a drum that defines a plurality of apertures in the outer surface for passing cooling gas;
b. depositing material on the web substrate; and
c. providing a cooling gas to the plurality of apertures that flows between the outer surface of the drum and the web substrate, thereby increasing heat transfer from the web substrate to the drum.

26. The method of claim 25 further comprising controlling the flow of the cooling gas, thereby controlling the heat transfer from the web substrate to the drum.

27. The method of claim 25 further comprising controlling the flow of the cooling gas so that a pressure proximate to the web substrate is in the range of 10-50 Torr.

28. The method of claim 25 further comprising depositing an elastomeric coating on the outer surface of the drum that increases heat transfer between the web substrate and the drum.

29. The method of claim 25 further comprising flowing cooling fluid through the drum to control a temperature of the drum.

30. The method of claim 25 further comprising covering at least some of the plurality of apertures in the outer surface of the drum that are not adjacent to the web substrate.

31. The method of claim 25 wherein the providing the cooling gas to the plurality of apertures causes a portion of the web substrate to float on a layer of trapped cooling gas, thereby allowing the portion of the web substrate to adjust its shape so as to reduce wrinkles.
